(19) United States
(12) Patent Application Publication
(10) Pub. No.: US 2011/0011731 A1
(43) Pub. Date: Jan. 20, 2011

(54) PROCESS FOR PRODUCING INDIUM OXIDE-TYPE TRANSPARENT ELECTROCONDUCTIVE FILM

(75) Inventors: Seiichiro Takahashi, Ageo-shi (JP); Norihiko Miyashita, Ageo-shi (JP)

Correspondence Address: SUGHRUE MION, PLLC, 2100 PENNSYLVANIA AVENUE, N.W., SUITE 800, WASHINGTON, DC, 20037, US

(73) Assignee: MITSUI MINING & SMELTING CO., LTD, Shinagawa-ku ,Tokyo (JP)

(21) Appl. No.: 12/593,797

(22) PCT Filed: Mar. 28, 2008
(86) PCT No.: PCT/JP2008/056104

§ 371 Date: Sep. 29, 2009

(30) Foreign Application Priority Data
Mar. 30, 2007 (JP) 2007-095782
Oct. 3, 2007 (JP) 2007-260437

(51) Int. Cl. C23C 14/08; C23C 14/34

(52) U.S. Cl. 204/192.1

(57) ABSTRACT

To provide a method for producing a method for producing a low-resistance and high-transmittance indium-oxide-based transparent conductive film readily obtained through crystallization, the method employing an amorphous film which can easily be patterned through etching with a weak acid.

The method of the invention includes a step of confirming that a sputtering target which is provided and which contains indium oxide and an additive element can deposit an amorphous film at a predetermined film deposition temperature, and that the deposited amorphous film can be crystallized through annealing at a predetermined annealing temperature; a step of determining, as a film deposition oxygen partial pressure, an oxygen partial pressure at which a crystallized film obtained through annealing at the predetermined annealing temperature has the lowest resistivity, which oxygen partial pressure differs from an optimum oxygen partial pressure at which the amorphous film deposited at the predetermined film deposition temperature has the lowest resistivity; a step of depositing an amorphous film through sputtering the sputtering target at the film deposition oxygen partial pressure; and a step of crystallizing the amorphous film through annealing at the predetermined annealing temperature, to thereby form an indium-oxide-based transparent conductive film.

### TECHNICAL FIELD

The present invention relates to a method for producing a low-resistance indium-oxide-based transparent conductive film readily obtained through crystallization, the method employing an amorphous film which can easily be patterned through etching with a weak acid.

### BACKGROUND ART

Indium oxide-tin oxide (In₂O₃—SnO₂ composite oxide, hereinafter abbreviated as “ITO”) film is a transparent conductive film which has high optical transparency with respect to visible light and high conductivity and which, therefore, finds a wide variety of applications, such as a liquid crystal display, a heat-generating film for defogging a glass panel, and an IR-reflecting film. However, difficulty is encountered in depositing such a transparent conductive film in an amorphous state.

There has been proposed a technique in which an amorphous ITO thin film or a quasi-amorphous ITO thin film deposited of ITO microcrystals, whose crystallographic feature is determined through X-ray diffractometry, is deposited on a substrate kept at 0° C. to 100° C., and then the ITO thin film is kept through annealing under reduced pressure or in a non-oxidizing atmosphere (see, for example, Patent Documents 1 and 2). However, such a technique is provided for a special purpose; i.e., the purpose of increasing the work function of the thin film surface. None of these patent documents describes that, for example, an amorphous film can be readily patterned by etching with a weak acid.

Meanwhile, indium oxide-zinc oxide (IZO) transparent conductive film, which is known as an amorphous film, poses a problem in that the film exhibits a transparency lower than that of ITO film and tends to be problematically yellowed.

In view of the foregoing, the present applicant previously proposed an amorphous transparent conductive film produced through adding silicon to a transparent ITO film and performing film deposition under predetermined conditions (see Patent Document 3). However, when silicon is added to a transparent conductive film, resistance of the film tends to increase, which is problematic.

When an indium oxide thin film deposited at an optimum oxygen partial pressure is thermally treated at high temperature, the resistance of the thus-treated film drastically increases due to reduction in carrier density and mobility. In order to solve such a problem, there has been proposed a method in which an indium oxide film is deposited in an atmosphere containing no oxygen or containing a small amount of oxygen, and the thus-obtained film is thermally treated (see, for example, Patent Documents 4 and 5). However, none of these patent documents describes, for example, an amorphous film or crystallization of an amorphous film.

Patent Document 1: Japanese Patent No. 3586906 (claims)
Patent Document 2: Japanese Patent No. 3849698 (claims)
Patent Document 3: Japanese Patent Application Laid-Open (kokai) No. 2005-135649 (claims)
Patent Document 4: Japanese Patent Application Laid-Open (kokai) No. 2006-97041 (claims)
Patent Document 5: Japanese Patent Application Laid-Open (kokai) No. 2006-99976 (claims)

### DISCLOSURE OF THE INVENTION

### Problems to be Solved by the Invention

In view of the foregoing, an object of the present invention is to provide a method for producing a low-resistance indium-oxide-based transparent conductive film which can readily obtained through crystallization, the method employing an amorphous film which can easily be patterned through etching with a weak acid.

### Means for Solving the Problems

In order to attain the aforementioned object, the present inventors have conducted extensive studies, and as a result have found that a film formation process including deposition of an amorphous film and crystallization of the thus-obtained film can be applied to an indium-oxide-based transparent conductive film containing various additive elements, that an oxygen partial pressure at which an amorphous film deposited at a predetermined film deposition temperature has the lowest resistivity (i.e., optimum oxygen partial pressure) may differ from an oxygen partial pressure at which a crystallized film obtained through annealing of the amorphous film has the lowest resistivity, and that, through utilization of this phenomenon, there can be attained a method for depositing a low-resistance and high-transparency film easily produced through crystallization, the method employing an amorphous film which can easily patterned through etching with a weak acid. The present invention has been accomplished on the basis of these findings.

In a first mode of the present invention for attaining the aforementioned object, there is provided a method for producing an indium-oxide-based transparent conductive film, characterized in that the method comprises:

a step of confirming that a sputtering target which is provided and which contains indium oxide and an additive element can produce an amorphous film at a predetermined film deposition temperature, and that the obtained amorphous film can be crystallized through annealing at a predetermined annealing temperature;

a step of determining an oxygen partial pressure at which a crystallized film obtained through annealing at the predetermined annealing temperature has the lowest resistivity, which oxygen partial pressure differs from an optimum oxygen partial pressure at which the amorphous film deposited at the predetermined film deposition temperature has the lowest resistivity, and employing the thus-determined oxygen partial pressure, as a film deposition oxygen partial pressure;

a step of producing an amorphous film through sputtering the sputtering target at the film deposition oxygen partial pressure; and

a step of crystallizing the amorphous film through annealing at the predetermined annealing temperature, to thereby produce an indium-oxide-based transparent conductive film.

According to the first mode, there can be attained a method for producing a low-resistance and high-transparency film readily produced through crystallization, the method employing an amorphous film which can easily patterned through etching with a weak acid. This method produces a transparent conductive film having such a composition that an amorphous film can be deposited at a predetermined film deposition temperature, and the produced amorphous film can be crystallized through annealing at a predetermined annealing temperature, wherein film deposition is carried out at an oxygen partial pressure at which a crystallized film obtained through annealing at the predetermined annealing temperature has the lowest resistivity, which oxygen partial pressure differs from an optimum oxygen partial pressure at which the amorphous film deposited at the predetermined film deposition temperature has the lowest resistivity.

A second mode of the present invention is directed to a specific embodiment of the method for producing an indium-oxide-based transparent conductive film of the first mode, wherein the method includes determining an optimum oxygen partial pressure at which a film produced at the annealing temperature has the lowest resistivity, and employing the thus-determined optimum oxygen partial pressure, as the film deposition oxygen partial pressure.

According to the second mode, an amorphous film is deposited at the film deposition oxygen partial pressure that is an optimum oxygen partial pressure at which a film produced at the annealing temperature has the lowest resistivity. Thus, there can be produced a transparent conductive film which exhibits the lowest resistivity after crystallization through annealing.

A third mode of the present invention is directed to a specific embodiment of the method for producing an indium-oxide-based transparent conductive film of the first or second mode, wherein the film deposition oxygen partial pressure is lower than the optimum oxygen partial pressure at which the produced amorphous film has the lowest resistivity.

According to the third mode, since the film deposition oxygen partial pressure is lower than the optimum oxygen partial pressure, advantageously, film deposition can be carried out at a low oxygen partial pressure.

A fourth mode of the present invention is directed to a specific embodiment of the method for producing an indium-oxide-based transparent conductive film of any of the first to third modes, wherein the film deposition temperature is lower than 100° C.

According to the fourth mode, an amorphous film can be deposited at lower than 100° C. and then crystallized through annealing, to thereby produce a transparent conductive film exhibiting low resistance.

A fifth mode of the present invention is directed to a specific embodiment of the method for producing an indium-oxide-based transparent conductive film of any of the first to fourth modes, wherein the additive element is at least one species selected from among Sn, Ba, Si, Sr, Li, La, Ca, Mg, and Y.

According to the fifth mode, since the sputtering target has a composition containing an additive element such as Sn, Ba, Si, Sr, Li, La, Ca, Mg, or Y, there can be realized a transparent conductive film having such a composition that an amorphous film can be deposited at a predetermined film deposition temperature, and the deposited amorphous film can be crystallized through annealing at a predetermined annealing temperature, and such that an optimum oxygen partial pressure at which the amorphous film deposited at the predetermined film deposition temperature has the lowest resistivity differs from an oxygen partial pressure at which a crystallized film obtained through annealing at the predetermined annealing temperature has the lowest resistivity.

A sixth mode of the present invention is directed to a specific embodiment of the method for producing an indium-oxide-based transparent conductive film of any of the first to fifth modes, wherein the additive element contains Sn and at least one species selected from among Ba, Si, Sr, Li, La, Ca, Mg, and Y.

According to the sixth mode, since the sputtering target has a composition containing, as additive elements, Sn and at least one species selected from among Ba, Si, Sr, Li, La, Ca, Mg, and Y, there can be realized a transparent conductive film having such a composition that an amorphous film can be produced at a predetermined film deposition temperature, and the produced amorphous film can be crystallized through annealing at a predetermined annealing temperature, and such that an optimum oxygen partial pressure at which the amorphous film deposited at the predetermined film deposition temperature has the lowest resistivity differs from an oxygen partial pressure at which a crystallized film obtained through annealing at the predetermined annealing temperature has the lowest resistivity.

A seventh mode of the present invention is directed to a specific embodiment of the method for producing an indium-oxide-based transparent conductive film of any of the first to sixth modes, wherein the amorphous film is etched with a weakly acidic etchant and then crystallized through annealing.

According to the seventh mode, since the amorphous film is etched with a weakly acidic etchant and then crystallized through annealing, the annealed film can be provided with resistance to weak acid.

An eighth mode of the present invention is directed to a specific embodiment of the method for producing an indium-oxide-based transparent conductive film of any of the first to seventh modes, wherein the annealing temperature falls within a range of 100 to 400° C.

According to the eighth mode, the amorphous film can be readily crystallized at a temperature of 100 to 400° C.

A ninth mode of the present invention is directed to a specific embodiment of the method for producing an indium-oxide-based transparent conductive film of any of the first to eighth modes, which produces an indium-oxide-based transparent conductive film having a resistivity of 1.0×10⁻⁴ to 1.0×10⁻³ Ω·cm.

According to the ninth mode, there can be produced an indium-oxide-based transparent conductive film having a resistivity of 1.0×10⁻⁴ to 1.0×10⁻³ Ω·cm.

### Effects of the Invention

According to the present invention employing a film Containing indium oxide and an additive element, there can be realized a transparent conductive film having such a composition that an amorphous film can be deposited at a predetermined film deposition temperature, and the produced amorphous film can be crystallized through annealing at a predetermined annealing temperature, and such that an optimum oxygen partial pressure at which the amorphous film deposited at the predetermined film deposition temperature has the lowest resistivity differs from an oxygen partial pressure at which a crystallized film obtained through annealing at the predetermined annealing temperature has the lowest resistivity. That is, the present invention produces a low-resistance transparent conductive film easily obtained through crystallization from an amorphous film which can be easily patterned with a weak acid.

### BRIEF DESCRIPTION OF THE DRAWINGS

FIG. 1 is a graph showing the relationship between oxygen partial pressure and resistivity obtained in Example 1.

FIG. 2 is a graph showing the relationship between oxygen partial pressure and resistivity obtained in Example 2.

FIG. 3 is a graph showing the relationship between oxygen partial pressure and resistivity obtained in Example 3.

FIG. 4 is a graph showing the relationship between oxygen partial pressure and resistivity obtained in Example 4.

FIG. 5 is graphs showing the relationship between oxygen partial pressure and resistivity obtained in Examples A1 to A3.

FIG. 6 is graphs showing the relationship between oxygen partial pressure and resistivity obtained in Examples A4 to A6.

FIG. 7 is graphs showing the relationship between oxygen partial pressure and resistivity obtained in Examples A7 and A8.

FIG. 8 is graphs showing the relationship between oxygen partial pressure and resistivity obtained in Examples A9 to A11.

FIG. 9 is graphs showing the relationship between oxygen partial pressure and resistivity obtained in Examples A12 to A14.

FIG. 10 is graphs showing the relationship between oxygen partial pressure and resistivity obtained in Examples A15 and A16.

FIG. 11 is a graph showing the relationship between oxygen partial pressure and resistivity obtained in Comparative Example A1.

FIG. 12 is a graph showing the relationship between oxygen partial pressure and resistivity obtained in Comparative Example A2.

FIG. 13 is a graph showing the relationship between oxygen partial pressure and resistivity obtained in Comparative Example A3.

FIG. 14 is a graph showing the relationship between oxygen partial pressure and resistivity obtained in Comparative Example A4.

FIG. 15 is a graph showing the relationship between oxygen partial pressure and resistivity obtained in Comparative Example A5.

FIG. 16 is a graph showing the relationship between oxygen partial pressure and resistivity obtained in Comparative Example A5.

### BEST MODES FOR CARRYING OUT THE INVENTION

The sputtering target employed for producing the indium-oxide-based transparent conductive film of the present invention contains indium oxide as a main component and an additive element.

The additive element is selected from among elements which realize a transparent conductive film having such a composition that an amorphous film can be deposited at a predetermined film deposition temperature, and the produced amorphous film can be crystallized through annealing at a predetermined annealing temperature, and such that an optimum oxygen partial pressure at which the amorphous film deposited at the predetermined film deposition temperature has the lowest resistivity differs from an oxygen partial pressure at which a crystallized film obtained through annealing at the predetermined annealing temperature has the lowest resistivity.

Specific examples of the additive element include Sn, Ba, Si, Sr, Li, La, Ca, Mg, and Y.

Generally, tin is added to indium-oxide-based transparent conductive film so as to attain low resistance. In the present invention, tin may be added as an essential element, and another element (e.g., Ba, Si, Sr, Li, La, Ca, Mg, or Y) may also be added for realizing a transparent conductive film having such a composition that an amorphous film can be deposited at a predetermined film deposition temperature, and the obtained amorphous film can be crystallized through annealing at a predetermined annealing temperature, and such that an optimum oxygen partial pressure at which the amorphous film deposited at the predetermined film deposition temperature has the lowest resistivity differs from an oxygen partial pressure at which a crystallized film obtained through annealing at the predetermined annealing temperature has the lowest resistivity.

No particular limitation is imposed on the amount of such an additive element, so long as there is attained such a composition that an amorphous film can be deposited at a predetermined film deposition temperature, and the produced amorphous film can be crystallized through annealing at a predetermined annealing temperature, and such that an optimum oxygen partial pressure at which the amorphous film deposited at the predetermined film deposition temperature has the lowest resistivity differs from an oxygen partial pressure at which a crystallized film obtained through annealing at the predetermined annealing temperature has the lowest resistivity.

In the case where only tin is incorporated as an additive element, when the amount of tin is 0.10 mol or more and less than 0.5 mol on the basis of 1 mol of indium, there is attained such a composition that an amorphous film can be deposited at a predetermined film deposition temperature, and such that an optimum oxygen partial pressure at which the amorphous film has the lowest resistivity differs from an oxygen partial pressure at which a crystallized film obtained through annealing at a predetermined annealing temperature has the lowest resistivity.

In the case where silicon is incorporated as an additive element, when silicon is added singly or in combination with tin, there is attained such a composition that an amorphous film can be deposited at a predetermined film deposition temperature, and such that an optimum oxygen partial pressure at which the amorphous film has the lowest resistivity differs from an oxygen partial pressure at which a crystallized film obtained through annealing at a predetermined annealing temperature has the lowest resistivity.

In this case, the amount of silicon is 0.02 to 0.06 mol on the basis of 1 mol of indium, and the amount of tin is 0 to 0.3 mol on the basis of 1 mol of indium.

In the case where barium is incorporated as an additive element, when barium is added singly or in combination with tin, there is attained such a composition that an amorphous film can be deposited at a predetermined film deposition temperature, and such that an optimum oxygen partial pressure at which the amorphous film has the lowest resistivity differs from an oxygen partial pressure at which a crystallized film obtained through annealing at a predetermined annealing temperature has the lowest resistivity.

In the aforementioned composition, the amount of barium is 0.00001 mol or more and less than 0.10 mol on the basis of 1 mol of indium, and the amount of tin is 0 to 0.3 mol on the basis of 1 mol of indium.

In the case where an element such as Sr, Li, La, Ca, Mg, or Y is incorporated, when the amount of such an element is 0.0001 mol or more and less than 0.10 mol on the basis of 1 mol of indium, effects similar to those described above can be attained.

A composition containing such an additive element together with Sn provides a marked change in optimum oxygen partial pressure. Therefore, a composition containing Zn together with Sn is thought to exhibit similar effects.

In the present invention, it is confirmed that an amorphous film can be deposited at a predetermined film deposition temperature, and the produced amorphous film can be crystallized through annealing at a predetermined annealing temperature, followed by determination of an oxygen partial pressure at which a crystallized film obtained through annealing at the predetermined annealing temperature has the lowest resistivity, which oxygen partial pressure differs from an optimum oxygen partial pressure at which the amorphous film deposited at the predetermined film deposition temperature has the lowest resistivity. The thus-determined oxygen partial pressure is employed as a film deposition oxygen partial pressure.

Such a film deposition oxygen partial pressure is determined by depositing films at a given film deposition temperature and at different oxygen partial pressures; annealing the thus-obtained films; and determining an oxygen partial pressure at which an annealed film has the lowest resistivity.

Such a film deposition oxygen partial pressure may be determined by depositing films at a given annealing temperature and at different oxygen partial pressures, and determining an optimum oxygen partial pressure at which a deposited film has the lowest resistivity.

Such a film deposition oxygen partial pressure differs from an optimum oxygen partial pressure at which film deposition is generally carried out. The film deposition oxygen partial pressure is generally lower than such an optimum oxygen partial pressure. However, a certain composition may provide a film deposition oxygen partial pressure higher than such an optimum oxygen partial pressure.

In the present invention, subsequently, an amorphous film is deposited through sputtering at the thus-determined film deposition oxygen partial pressure.

The film deposition temperature, which varies with, film composition, is determined so as to fall within a range of room temperature or higher and lower than the temperature at which the film is crystallized. For example, the film deposition temperature is lower than 200° C., preferably lower than 150° C., more preferably lower than 100° C. Preferably, the film is deposited in an amorphous state at such a temperature.

Such an amorphous film is advantageous in that the film can be etched with a weakly acidic etchant. As used herein, “etching” is included in the patterning step and is carried out for forming a predetermined pattern.

Thereafter, the thus-obtained amorphous film is crystallized through annealing at a predetermined annealing temperature, to thereby produce a transparent conductive film having such a composition that the lowest resistance is attained.

The thus-obtained transparent conductive film preferably has a resistivity of, for example, 1.0×10⁻⁴ to 1.0×10⁻³ Ω·cm.

The crystallized transparent conductive film exhibits enhanced etching resistance and cannot be etched with a weakly acidic etchant, which can etch an amorphous film. Thus, the crystallized film is advantageous in that it exhibits enhanced corrosion resistance, moisture resistance, and environmental resistance in the subsequent steps.

In general, the transparent conductive film crystallized through annealing exhibits a transparency higher than that of an amorphous film. Preferably, the transparent conductive film exhibits, for example, an average transmittance at a wavelength of 400 to 500 nm of 85% or higher.

The annealing temperature is preferably a temperature of 100° C. to 400° C. Since such a temperature range is generally employed in semiconductor manufacturing processes, crystallization may be carried out in such a manufacturing process. Within the aforementioned temperature range, the film is preferably crystallized at 150° C. to 300° C., more preferably at 200° C. to 250° C.

When the method of the present invention is carried out, a film is deposited at a predetermined film deposition temperature by use of a sputtering target having a desired composition. The method of the present invention produces a transparent conductive film having a chemical composition identical to or very similar to that of the sputtering target.

When a film is deposited by use of such a sputtering target, DC magnetron sputtering may be carried out, or a high-frequency magnetron sputtering apparatus may be employed.

The chemical composition of an indium-oxide-based transparent conductive film deposited through sputtering may be analyzed by dissolving the entirety of a single film and analyzing the solution through ICP. Alternatively, when, for example, the film itself forms a device component, a portion to be analyzed is optionally cut by means of FIB or a similar apparatus, and can be characterized by means of an elemental analyzer (e.g., EDS, WDS, or Auger analyzer) attached to an SEM, a TEM, or a similar device.

Next will be described the method for producing the sputtering target employed in the present invention. However, the method is not particularly limited to the following procedure, which is merely an exemplary method.

The sputtering target is produced by mixing raw material powders corresponding to the chemical composition of a transparent conductive film in desired proportions, and compacting the resultant mixture. No particular limitation is imposed on the method of compacting the mixture, and the mixture is compacted through any of conventionally known wet methods and dry methods.

Examples of the dry method include the cold press method and the hot press method. The cold press method includes charging a mixed powder into a mold to form a compact and firing the compact. The hot press method includes firing a mixed powder placed in a mold for sintering.

Examples of preferred wet methods include a filtration molding method (see Japanese Patent Application Laid-Open (kokai) No. H11-286002). The filtration molding method employs a filtration mold, formed of a water-insoluble material, for removing water under reduced pressure from a ceramic raw material slurry, to thereby produce a compact, the filtration mold including a lower mold having one or more water-discharge holes; a water-passing filter for placement on the lower mold; a seal material for sealing the filter; and a mold frame for securing the filter from the upper side through intervention of the seal material. The lower mold, mold frame, seal material, and filter, which can be separated from one another, are assembled to thereby form the filtration mold. According to the filtration molding method, water is removed under reduced pressure from the slurry only from the filter side. In a specific operation making use of the filtration mold, a powder mixture, ion-exchange water, and an organic additive are mixed, to thereby prepare a slurry, and the slurry is poured into the filtration mold. Water contained in the slurry is removed under reduced pressure from only the filter side, to thereby produce a compact. The resultant ceramic compact is dried, debindered, and fired.

The temperature at which the compact produced through the cold press method or the wet method is fired is preferably 1,300 to 1,650° C., more preferably 1,500 to 1,650° C. The firing atmosphere is air, oxygen, a non-oxidizing atmosphere, vacuum, etc. In the case where the hot press method is employed, the compact is preferably sintered at about 1,200° C., and the atmosphere is a non-oxidizing atmosphere, vacuum, etc. In each method, after firing, the fired compact is mechanically worked so as to form a target having predetermined dimensions.

### EXAMPLES

The present invention will next be described by way of examples, which should not be construed as limiting the invention thereto.

### Example 1

A >99.99%-purity In₂O₃ powder, a >99.99%-purity SnO₂ powder, and a >99.9%-purity SiO₂ powder were provided. These powders (total: about 2.5 Kg) were provided so that Si and Sn were respectively about 0.026 mol and 0.1 mol on the basis of 1 mol of In. The powders were formed into a compact through a filtration molding method. Thereafter, the compact was fired in an oxygen atmosphere at 1,550° C. for eight hours, to thereby produce a sintered compact. The sintered compact was processed, to thereby produce a target having a density of 7.01 g/cm³ (relative density of 100% with respect to the theoretical density). The target was found to exhibit a bulk resistivity of 2.4×10⁻⁴ Ω·cm.

While the oxygen partial pressure was varied from 0 to 4.0 sccm (corresponding to 0 to 2.0×10⁻² Pa), a film (thickness: 1,200 Å) was deposited from the thus-obtained target through DC magnetron sputtering under the following conditions.

Target dimensions: φ=8 inches, t=6 mm
Mode of sputtering: DC magnetron sputtering
Evacuation apparatus: Rotary pump+cryopump
Vacuum attained: 2.2×10⁻⁴ [Pa]
Ar pressure: 4.0×10⁻¹ [Pa]
Oxygen pressure: 0 to 2.0×10⁻² [Pa]
Substrate temperature: 100° C.

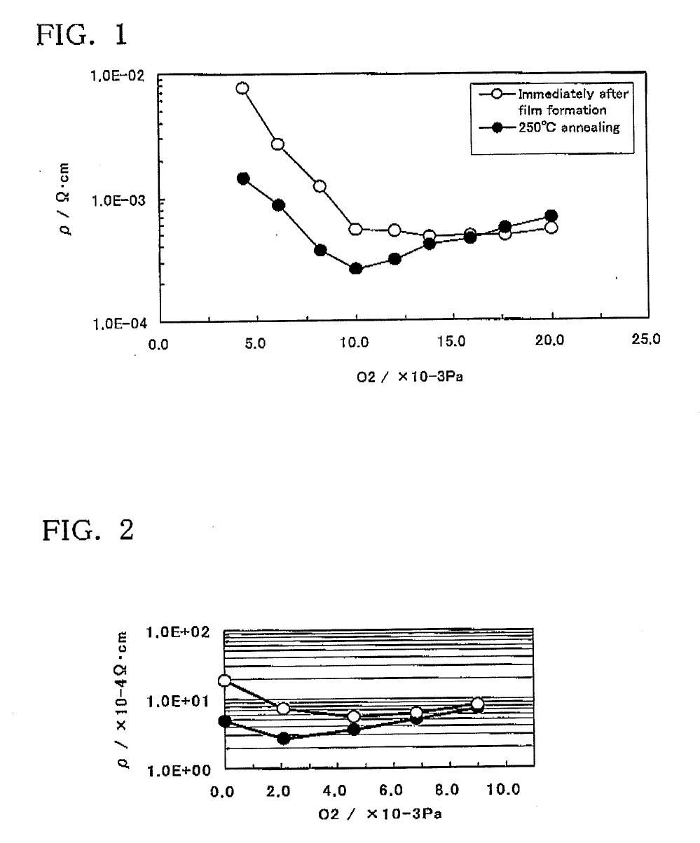

The resistivities of films deposited at different oxygen partial pressures were measured, and then the resistivity of each of the films was measured after annealing at 250° C. The results are shown in FIG. 1.

The optimum oxygen partial pressure for deposition of a film at 100° C. was found to be 1.38×10⁻² Pa (resistivity: 4.79×10⁻⁴ Ω·cm), and the oxygen partial pressure for deposition of a film exhibiting the lowest resistivity after 250° C. annealing was found to be 1.0×10⁻² Pa (resistivity: 2.60×10⁻⁴ Ω·cm).

This data indicates that when a film is deposited at 100° C. and at an oxygen partial pressure of 1.0×10⁻² Pa and then annealed at 250° C., the resultant film exhibits the lowest resistivity.

### Examples 2 and 3

A >99.99%-purity In₂O₃ powder, a >99.99%-purity SnO₂ powder, and a >99.9%-purity BaCO₃ powder were provided.

Firstly, In₂O₃ powder (BET=27 m²/g) (58.5 wt. %) and BaCO₃ powder (BET=1.3 m²/g) (41.4 wt. %) (total: 200 g) were mixed by means of a ball mill in a dry state, and the mixture was calcined in air at 1,100° C. for three hours, to thereby yield BaIn₂O₄ powder.

Subsequently, the above-obtained BaIn₂O₄ powder, In₂O₃ powder (BET=5 m²/g), and SnO₂ powder (BET=1.5 m²/g) (total: about 1.0 kg) were provided so that Ba and Sn were respectively 0.02 mol and 0.1 mol on the basis of 1 mol of In (Example 2), or so that Ba and Sn were respectively 0.005 mol and 0.3 mol on the basis of 1 mol of In (Example 3). These powders were mixed by means of a ball mill. Subsequently, the mixture was mixed with an aqueous PVA solution serving as a binder, dried, and cold-pressed, to thereby prepare a compact. The compact was debindered in air at 600° C. for 10 hours with temperature elevation at 60 degrees (° C.)/h, and then fired in an oxygen atmosphere at 1,600° C. for eight hours, to thereby produce a sintered compact. In the firing process, specifically, the temperature was elevated from room temperature to 800° C. at 100 degrees (° C.)/h and from 800° C. to 1,600° C. at 400 degrees (° C.)/h, was kept at 1,600° C. for eight hours, and was lowered from 1,600° C. to room temperature at 100 degrees (° C.)/h. Thereafter, the sintered compact was processed, to thereby produce a target. The target corresponding to the chemical composition of Example 2 was found to have a density of 6.96 g/cm³ and to exhibit a bulk resistivity of 2.87×10⁻⁴ Ω·cm, and the target corresponding to the chemical composition of Example 3 was found to have a density of 6.61 g/cm³ and to exhibit a bulk resistivity of 4.19×10⁻⁴ Ω·cm.

Each of the sputtering targets produced in Examples 2 and 3 was placed in a 4-inch DC magnetron sputtering apparatus. Transparent conductive films of Examples 2 and 3 were deposited at a substrate temperature of about 20° C. (room temperature) while the oxygen partial pressure was varied from 0 to 3.0 sccm (corresponding to 0 to 1.1×10⁻² Pa).

Each target was subjected to sputtering under the following conditions, whereby a film having a thickness of 1,200 Å was produced.

Target dimensions: φ=4 inches, t=6 mm
Mode of sputtering: DC magnetron sputtering
Evacuation apparatus: Rotary pump+cryopump
Vacuum attained: 5.3×10⁻⁶ [Pa]
Ar pressure: 4.0×10⁻¹ [Pa]
Oxygen pressure: 0 to 1.1×10⁻² [Pa]
Substrate temperature: room temperature
Electric power for sputtering: 130 W (power density: 1.6 W/cm²)
Substrate used: Corning #1737 (glass sheet for liquid crystal display, t=0.8 mm)

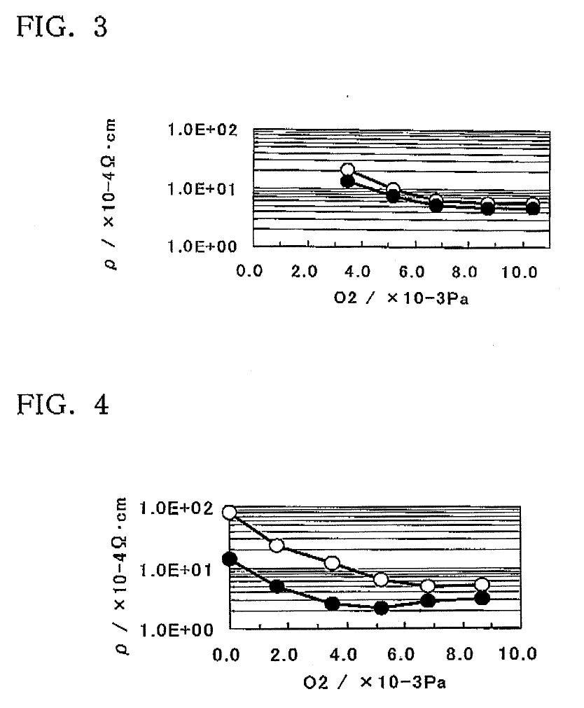

The resistivities of films deposited at different oxygen partial pressures were measured, and then the resistivity of each of the films was measured after annealing at 250° C. The results are shown in FIGS. 2 and 3.

In Example 2, the optimum oxygen partial pressure for deposition of a film at room temperature was found to be 4.6×10⁻³ Pa (resistivity: 5.5×10⁻⁴ Ω·cm), and the oxygen partial pressure for deposition of a film exhibiting the lowest resistivity after 250° C. annealing was found to be 2.1×10⁻³ Pa (resistivity: 2.7×10⁻¹ Ω·cm).

This data indicates that, in the case of the chemical composition of Example 2, when an amorphous film is deposited at room temperature and at an oxygen partial pressure of 2.1×10⁻³ Pa, which is lower than the optimum oxygen partial pressure, and the produced amorphous film is subjected to etching (including patterning), followed by crystallization through annealing at 250° C., a transparent conductive film exhibiting a resistivity of 2.7×10⁻⁴ Ω·cm is produced.

In Example 3, the optimum oxygen partial pressure for deposition of a film at room temperature was found to be 8.7×10⁻³ Pa (resistivity: 5.7×10⁻⁴ Ω·cm), and the oxygen partial pressure for deposition of a film exhibiting the lowest resistivity after 250° C. annealing was found to be 10.4×10⁻³ Pa (resistivity: 4.7×10⁻⁴ Ω·cm).

This data indicates that, in the case of the chemical composition of Example 3, when an amorphous film is deposited at room temperature and at an oxygen partial pressure of 10.4×10⁻³ Pa, which is higher than the optimum oxygen partial pressure, and the produced amorphous film is subjected to etching (including patterning), followed by crystallization through annealing at 250° C., a transparent conductive film exhibiting a resistivity of 4.7×10⁻⁴ Ω·cm is produced.

### Example 4

In₂O₃ powder (BET=5 m²/g) and SnO₂ powder (total: about 1.0 kg) were provided so that Sn was 0.25 mol on the basis of 1 mol of In. These powders were mixed by means of a ball mill. Subsequently, the mixture was mixed with an aqueous PVA solution serving as a binder, dried, and cold-pressed, to thereby prepare a compact. The compact was debindered in air at 600° C. for 10 hours with temperature elevation at 60 degrees (° C.)/h, and then fired in an oxygen atmosphere at 1,600° C. for eight hours, to thereby produce a sintered compact. In the firing process, specifically, the temperature was elevated from room temperature to 800° C. at 100 degrees (° C.)/h and from 800° C. to 1,600° C. at 400 degrees (° C.)/h, was kept at 1,600° C. for eight hours, and was lowered from 1,600° C. to room temperature at 100 degrees (° C.)/h. Thereafter, the sintered compact was processed, to thereby produce a target having a density of 7.14 g/cm³. The target was found to exhibit a bulk resistivity of 2.90×10⁻⁴ Ω·cm.

Film deposition was carried out under the same conditions as in the case of Examples 2 and 3. The resistivities of films deposited at different oxygen partial pressures were measured, and then the resistivity of each of the films was measured after annealing at 250° C. The results are shown in FIG. 4.

In Example 4, the optimum oxygen partial pressure for deposition of a film at room temperature was found to be 6.8×10⁻³ Pa (resistivity: 5.1×10⁻⁴ Ω·cm), and the oxygen partial pressure for deposition of a film exhibiting the lowest resistivity after 250° C. annealing was found to be 5.2×10⁻³ Pa (resistivity: 2.2×10⁻⁴ Ω·cm).

This data indicates that, in the case of the chemical composition of Example 4, when an amorphous film is deposited at room temperature and at an oxygen partial pressure of 5.2×10⁻³ Pa, which is lower than the optimum oxygen partial pressure, and the produced amorphous film is subjected to etching (including patterning), followed by crystallization through annealing at 250° C., a transparent conductive film exhibiting a resistivity of 2.2×10⁻⁴ Ω·cm is produced.

### (Sputtering Target Production Example A1) (Sr—ITO)

### (Sr-Added ITO, Sr=0.02, Sn=0.1)

A >99.99%-purity In₂O₃ powder, a >99.99%-purity SnO₂ powder, and a >99.9%-purity SrCO₃ powder were provided. Firstly, In₂O₃ powder (65.3 wt. %) and SrCO₃ powder (34.7 wt. %) (total: 200 g) were mixed by means of a ball mill in a dry state, and the mixture was calcined in air at 1,200° C. for three hours, to thereby yield SrIn₂O₄ powder.

Subsequently, the above-obtained SrIn₂O₄ powder (2.2 wt. %), In₂O₃ powder (86.6 wt. %), and SnO₂ powder (11.2 wt. %) (total: about 1.0 kg) were provided (metal atom proportions: In=88.0 at. %, Sn=10.0 at. %, Sr=2.0 at. %), and these powders were mixed by means of a ball mill. Subsequently, the mixture was mixed with an aqueous PVA solution serving as a binder, dried, and cold-pressed, to thereby prepare a compact. The compact was debindered in air at 600° C. for 10 hours with temperature elevation at 60 degrees (° C.)/h, and fired in an oxygen atmosphere at 1,550° C. for eight hours, to thereby produce a sintered compact. In the firing process, specifically, the temperature was elevated from room temperature to 800° C. at 200 degrees (° C.)/h and from 800° C. to 1,550° C. at 400 degrees (° C.)/h, was kept at 1,550° C. for eight hours, and was lowered from 1,550° C. to room temperature at 100 degrees (° C.)/h. Thereafter, the sintered compact was processed, to thereby produce a target. The target was found to have a density of 7.05 g/cm³.

In a manner similar to that described above, sputtering targets (Sr=0.00001, 0.01, and 0.05) were produced.

### (Sputtering Target Production Example A2) (Li-ITO)

### (Li-Added ITO, Li=0.02, Sn=0.1)

A >99.99%-purity In₂O₃ powder, a >99.99%-purity SnO₂ powder, and a >99.9%-purity Li₂CO₃ powder were provided.

Firstly, In₂O₃ powder (79.0 wt. %) and Li₂CO₃ powder (21.0 wt. %) (total: 200 g) were mixed by means of a ball mill in a dry state, and the mixture was calcined in air at 1,000° C. for three hours, to thereby yield LiInO₂ powder.

Subsequently, the procedure of production of Sr—ITO (Sr=0.02) was repeated, except that the above-obtained LiInO₂ powder (2.2 wt. %), In₂O₃ powder (86.8 wt. %), and SnO₂ powder (11.0 wt. %) (total: about 1.0 kg) were provided (metal atom proportions: In=88.0 at. %, Sn=10.0 at. %, Li=2.0 at. %), and that the firing temperature was changed to 1,450° C., to thereby prepare a target. The target was found to have a density of 6.85 g/cm³.

In a manner similar to that described above, sputtering targets (Li=0.00005, 0.01, and 0.05) were produced.

### (Sputtering Target Production Example A3) (La-ITO)

### (La-Added ITO, La=0.02, Sn=0.1)

A >99.99%-purity In₂O₃ powder, a >99.99%-purity SnO₂ powder, and a >99.99%-purity La₂(CO₃)₃.8H₂O powder were provided.

Firstly, In₂O₃ powder (31.6 wt. %) and La₂(CO₃)₃.8H₂O powder (68.4 wt. %) (total: 200 g) were mixed by means of a ball mill in a dry state, and the mixture was calcined in air at 1,200° C. for three hours, to thereby yield LaInO₃ powder.

Subsequently, the procedure of production of Sr—ITO (Sr=0.02) was repeated, except that the above-obtained LaInO₃ powder (4.3 wt. %), In₂O₃ powder (85.0 wt. %), and SnO₂ powder (10.7 wt. %) (total: about 1.0 kg) were provided (metal atom proportions: In=88.0 at. %, Sn=10.0 at. %, La=2.0 at. %), to thereby prepare a target. The target was found to have a density of 7.04 g/cm³.

In a manner similar to that described above, sputtering targets (La=0.00008 and 0.01) were produced.

### (Sputtering Target Production Example A4) (Ca-ITO)

### (Ca-Added ITO, Ca=0.02, Sn=0.1)

A >99.99%-purity In₂O₃ powder, a >99.99%-purity SnO₂ powder, and a >99.5%-purity CaCO₃ powder were provided.

Firstly, In₂O₃ powder (73.5 wt. %) and CaCO₃ powder (26.5 wt. %) (total: 200 g) were mixed by means of a ball mill in a dry state, and the mixture was calcined in air at 1,200° C. for three hours, to thereby yield CaIn₂O₄ powder.

Subsequently, the procedure of production of Sr—ITO (Sr=0.02) was repeated, except that the above-obtained CaIn₂O₄ powder (4.8 wt. %), In₂O₃ powder (84.3 wt. %), and SnO₂ powder (10.9 wt. %) (total: about 1.0 kg) were provided (metal atom proportions: In=88.0 at. %, Sn=10.0 at. %, Ca=2.0 at. %), to thereby prepare a target. The target was found to have a density of 6.73 g/cm³.

In a manner similar to that described above, sputtering targets (Ca=0.0001, 0.05, and 0.10) were produced.

### (Sputtering Target Production Example A5) (Mg-ITO)

### (Mg-Added ITO, Mg=0.02, Sn=0.1)

A >99.99%-purity In₂O₃ powder, a >99.99%-purity SnO₂ powder, and a magnesium hydroxide carbonate powder (MgO content: 41.5 wt. %) were provided.

Firstly, In₂O₃ powder (87.3 wt. %) and magnesium hydroxide carbonate powder (12.7 wt. %) (total: 200 g) were mixed by means of a ball mill in a dry state, and the mixture was calcined in air at 1,400° C. for three hours, to thereby yield MgIn₂O₄ powder.

Subsequently, the procedure of production of Sr—ITO (Sr=0.02) was repeated, except that the above-obtained MgIn₂O₄ powder (4.6 wt. %), In₂O₃ powder (84.5 wt. %), and SnO₂ powder (10.9 wt. %) (total: about 1.0 kg) were provided (metal atom proportions: In=88.0 at. %, Sn=10.0 at. %, Mg=2.0 at. %), to thereby prepare a target. The target was found to have a density of 7.02 g/cm³.

In a manner similar to that described above, sputtering targets (Mg=0.001, 0.05, and 0.12) were produced.

### (Sputtering Target Production Example A6) (Y-ITO)

### (Y-Added ITO, Y=0.02)

A >99.99%-purity In₂O₃ powder, a >99.99%-purity SnO₂ powder, and a >99.99%-purity Y₂(CO₃)₃.3H₂O powder were provided.

Firstly, In₂O₃ powder (40.2 wt. %) and Y₂(CO₃)₃.3H₂O powder (59.8 wt. %) (total: 200 g) were mixed by means of a ball mill in a dry state, and the mixture was calcined in air at 1,200° C. for three hours, to thereby yield YInO₃ powder.

Subsequently, the procedure of production of Sr—ITO (Sr=0.02) was repeated, except that the above-obtained YInO₃ powder (3.6 wt. %), In₂O₃ powder (85.6 wt. %), and SnO₂ powder (10.8 wt. %) (total: about 1.0 kg) were provided (metal atom proportions: In=88.0 at. %, Sn=10.0 at. %, Y=2.0 at. %), to thereby prepare a target. The target was found to have a density of 7.02 g/cm³.

In a manner similar to that described above, sputtering targets (Y=0.05 and 0.15) were produced.

### Examples A1 to A16 and Comparative Examples A1 to A6

Examples A1 to A16 and Comparative Examples A1 to A6 were carried out as described below.

As shown in Table 1, the targets produced in Production Examples A1 to A6 were employed as targets for Examples A1 to A16 and Comparative Examples A1 to A6. Each target was placed in a 4-inch DC magnetron sputtering apparatus. Transparent conductive films of the Examples and Comparative Examples were formed from the corresponding targets at a substrate temperature of about 20° C. (room temperature) while the oxygen partial pressure was varied from 0 to 3.0 sccm (corresponding to 0 to 1.1×10⁻² Pa).

TABLE 1

| Additive | | | | | |
|---|---|---|---|---|---|
| element | Composition | | | | |
| Sr | Comparative | Example A1 | Example A2 | Example A3 | |
| | Example A1 | (Sr = 0.01) | (Sr = 0.02) | (Sr = 0.05) | |
| | (Sr = 0.00001) | | | | |
| Li | Comparative | Example A4 | Example A5 | Example A6 | |
| | Example A2 | (Li = 0.01) | (Li = 0.02) | (Li = 0.05) | |
| | (Li = 0.00005) | | | | |
| La | Comparative | Example A7 | Example A8 | — | |
| | Example A3 | (La = 0.01) | (La = 0.02) | | |
| | (La = 0.00008) | | | | |
| Ca | Example A15 | — | Example A9 | Example A10 | Comparative |
| | (Ca = 0.0001) | | (Ca = 0.02) | (Ca = 0.05) | Example A4 |
| | | | | | (Ca = 0.10) |
| Mg | Example A16 | — | Example A11 | Example A12 | Comparative |
| | (Mg = 0.001) | | (Mg = 0.02) | (Mg = 0.05) | Example A5 |
| | | | | | (Mg = 0.12) |
| Y | | — | Example A13 | Example A14 | Comparative |
| | | | (Y = 0.02) | (Y = 0.05) | Example A6 |
| | | | | | (Y = 0.15) |

Each target was subjected to sputtering under the following conditions, whereby a film having a thickness of 1,200 Å was deposited.

Target dimensions: φ=4 inches, t=6 mm
Mode of sputtering: DC magnetron sputtering
Evacuation apparatus: Rotary pump+cryopump
Vacuum attained: 5.3×10⁻⁶ [Pa]
Ar pressure: 4.0×10⁻¹ [Pa]
Oxygen pressure: 0 to 1.1×10⁻² [Pa]
Water pressure: 5.0×10⁻⁶ [Pa]
Substrate temperature: room temperature
Electric power for sputtering: 130 W (power density: 1.6 W/cm²)
Substrate used: Corning #1737 (glass sheet for liquid crystal display, t=0.8 mm)

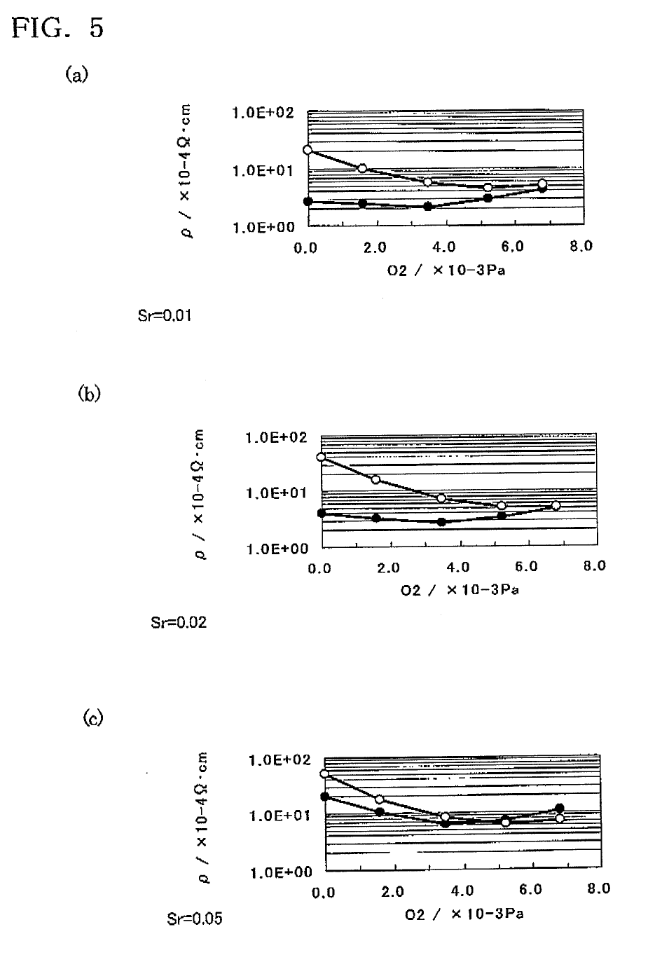

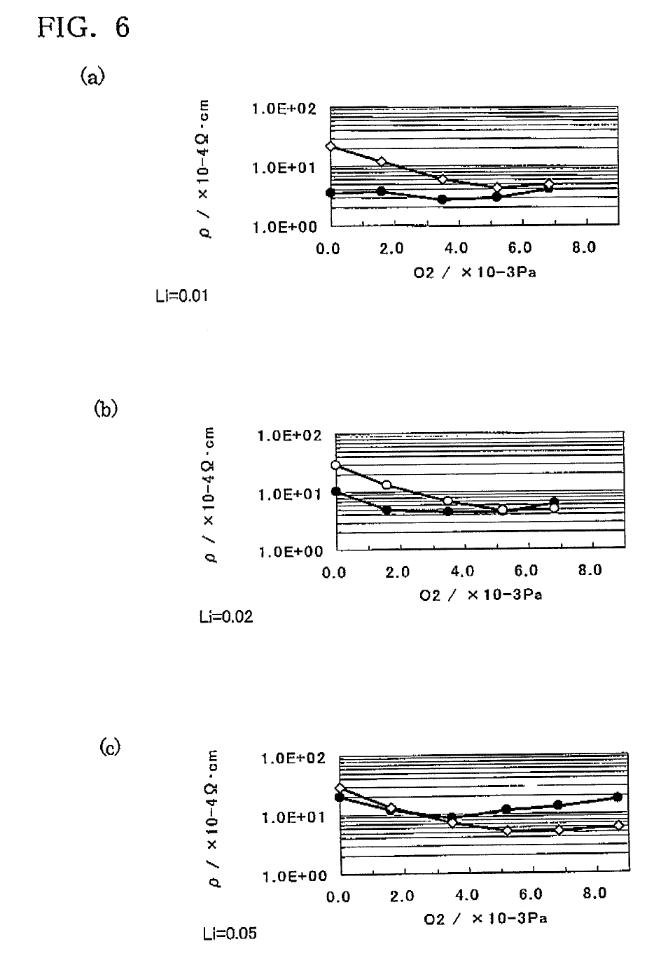

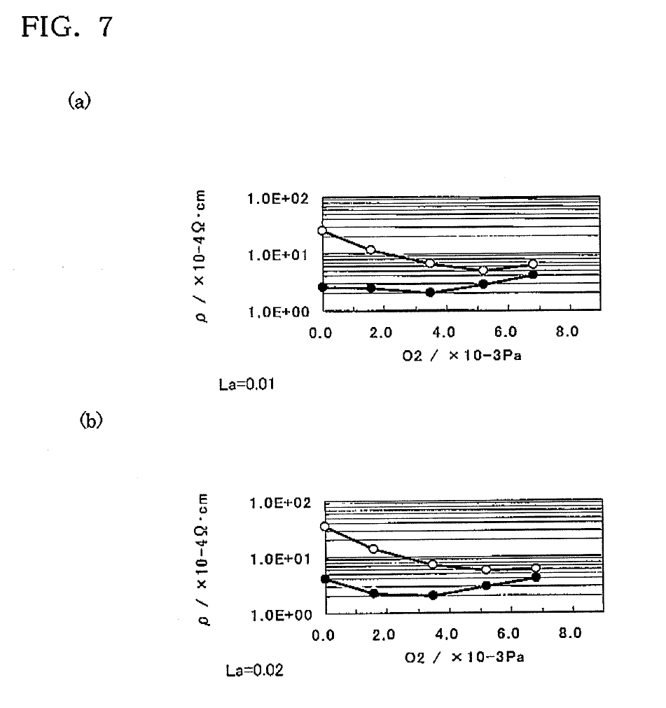

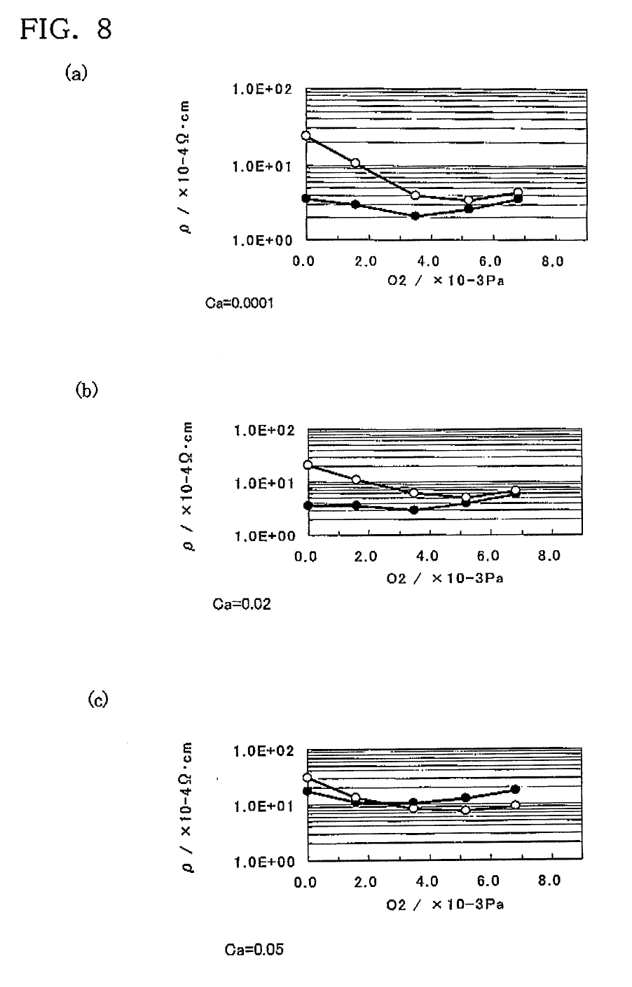

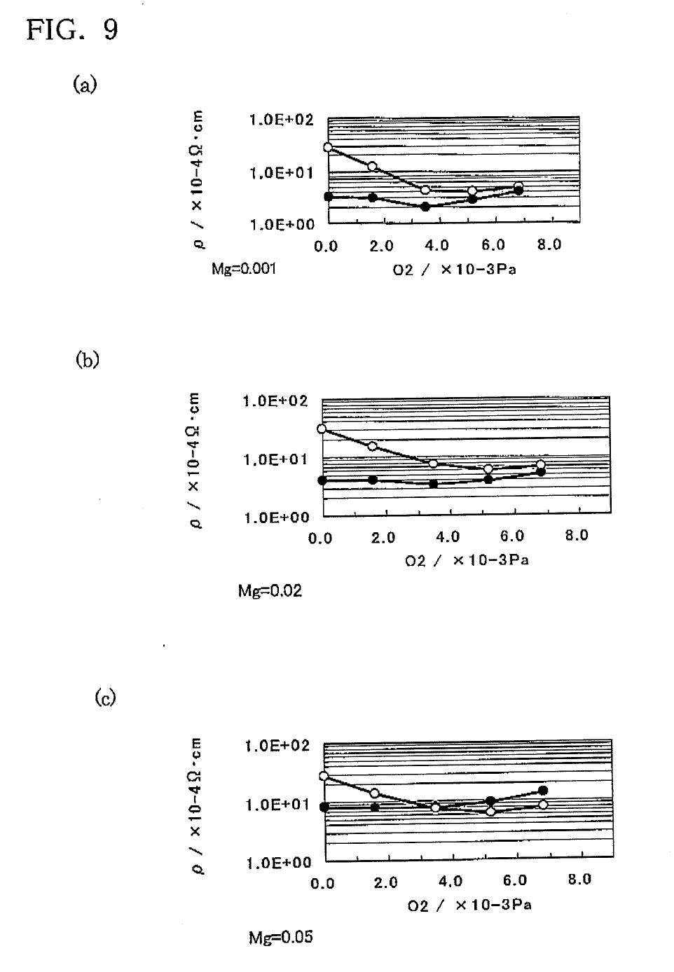

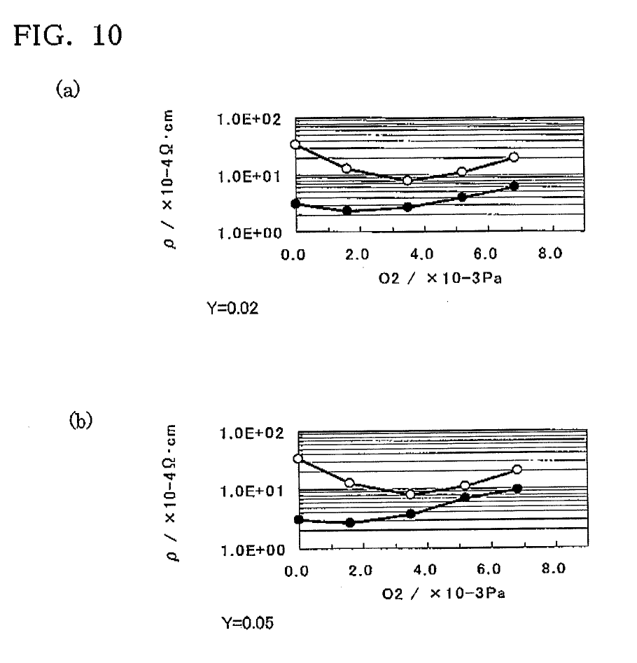

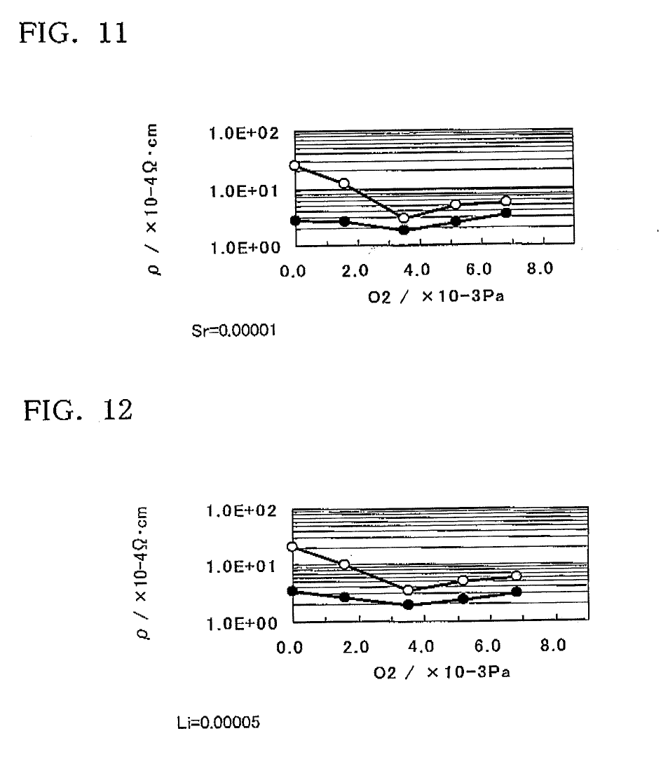

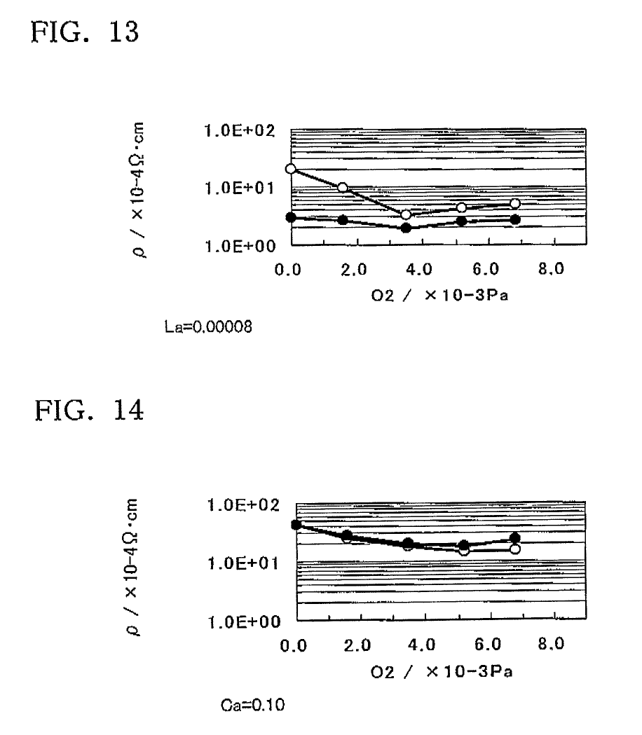

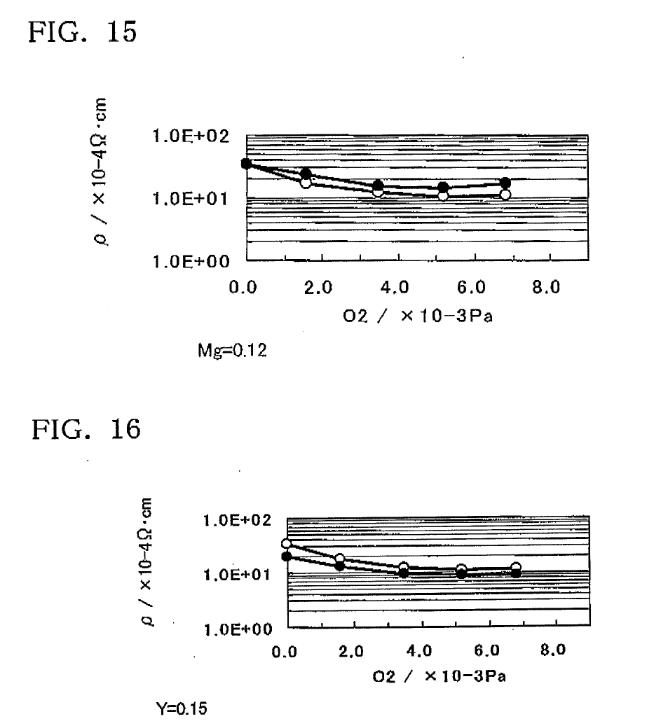

The resistivities of films deposited at different oxygen partial pressures were measured, and then the resistivity of each of the films was measured after annealing at 250° C. The results are shown in FIGS. 5 to 16.

This data showed the presence of optimum oxygen partial pressure in any of the Examples and Comparative Examples.

In Examples A1 to A16, the optimum oxygen partial pressure for deposition of a film at room temperature was found to differ from oxygen partial pressure for deposition of a film exhibiting the lowest resistivity after 250° C. annealing. Table 2 shows optimum oxygen partial pressure for deposition of a film at room temperature, as well as oxygen partial pressure for formation of a film exhibiting the lowest resistivity after 250° C. annealing. Thus, this data indicates that, in the cases of Examples A1 to A16, when film deposition is carried out at an oxygen partial pressure for deposition of a film exhibiting the lowest resistivity after 250° C. annealing, and then annealing is performed at 250° C., the resultant film exhibits the lowest resistivity.

In contrast, in Comparative Examples A1 to A3, in which an additive element was incorporated in an excessively small amount, or in Comparative Examples A4 to A6, in which an additive element was incorporated in an excessively large amount, optimum oxygen partial pressure for deposition of a film at room temperature was found not to differ from oxygen partial pressure for deposition of a film exhibiting the lowest resistivity after 250° C. annealing; i.e., no shift in optimum oxygen partial pressure was observed.

In the column “shift in optimum oxygen partial pressure” of Table 2, “◯” represents the presence of a shift in optimum oxygen partial pressure, whereas “x” represents the absence of a shift in optimum oxygen partial pressure.

### Test Example A1

Each of the transparent conductive films deposited at room temperature in Examples A1 to A16 was cut into pieces (13 mm×13 mm each), and the resultant samples were annealed in air at 300° C. for one hour. Table 2 shows the crystal state (upon film deposition at room temperature, and after annealing at 250° C.) of each of the samples of Examples A1 to A16 and Comparative Examples A1 to A6 (a: amorphous, c: crystallized).

The data in Table 2 showed that, in Examples A1 to A16, a film was deposited in an amorphous state at room temperature, and the amorphous film was crystallized through annealing at 250° C. for one hour. The data also showed that, in Comparative Examples A4 to A6 (in which an additive element was incorporated in a large amount), a film was deposited in an amorphous state at room temperature, but the amorphous film was not crystallized through annealing at 250° C., whereas in Comparative Examples A1 to A3 (in which an additive element was incorporated in a small amount), a film was crystallized upon film deposition at room temperature; i.e., an amorphous film failed to be deposited.

### Test Example A2

The resistivity ρ (Ω·cm) of the transparent conductive films deposited at room temperature and at an optimum oxygen partial pressure was determined. The resistivity of the sample of Test Example A1 which had undergone annealing was also determined. The results are shown in Table 2.

As shown in Table 2, the films of Examples A1 to A16 and Comparative Examples A1 to A3 exhibited a resistivity on the order of 10⁻⁴ Ω·cm.

In contrast, the films of Comparative Examples A4 to A6 were found to exhibit a higher resistivity; i.e., a resistivity on the order of 10⁻³ Ω·cm or around 10⁻³ Ω·cm.

### Test Example A3

Each of the transparent conductive films deposited at room temperature and at an optimum oxygen partial pressure in examples A1 to A16 was cut into pieces (13 mm×13 mm each), and the transmission spectra of the resultant samples were determined. In a similar manner, the transmission spectrum of the film of Test Example A1 which had undergone annealing was also determined. The average transmittance values, after annealing, of the samples of Examples A1 to A16 and Comparative Examples A1 to A6 are shown in Table 2.

This data showed that, as compared with the transmission spectra of the as-deposited film samples (before annealing), the absorption edge was blue-shifted through annealing at 300° C. for one hour, thereby providing a more suitable color of the samples.

### Test Example A4

Each of the transparent conductive films deposited at room temperature and at an optimum oxygen partial pressure in Examples A1 to A16 was cut into pieces (10×50 mm each), and etchability of the samples was tested at 30° C. by use of an etchant (ITO-05N, oxalic acid-based, product of Kanto Chemical Co., Inc.) (oxalic acid concentration: 50 g/L). The sample of Test Example 1 which had undergone annealing was also tested in a similar manner. The results are shown in Table 2, with the ratings “◯” (etchable) and “x” (unetchable).

As is clear from Table 2, an amorphous film can be etched with a weakly acidic etchant, but a crystallized film cannot be etched.

TABLE 2

| Examples/ | | | | Chemical Composition [at. %] | | | Ratio to 1 | Shift In optimum |
|---|---|---|---|---|---|---|---|---|
| Comparative | | Sample | Additive | | | Additive | mol of In | oxygen partial pressure |
| Examples | | Name | element | In | Sn | element | [mol] | [∘ or x] |
| Ex. | A1 | Sr = 0.01 | Sr | 89.0 | 10.0 | 1.0 | 0.011 | ∘ |
| | A2 | Sr = 0.02 | Sr | 88.0 | 10.0 | 2.0 | 0.023 | ∘ |
| | A3 | Sr = 0.05 | Sr | 85.0 | 10.0 | 5.0 | 0.059 | ∘ |
| | A4 | Li = 0.01 | Li | 89.0 | 10.0 | 1.0 | 0.011 | ∘ |
| | A5 | Li = 0.02 | Li | 88.0 | 10.0 | 2.0 | 0.023 | ∘ |
| | A6 | Li = 0.05 | Li | 85.0 | 10.0 | 5.0 | 0.059 | ∘ |
| | A7 | La = 0.01 | La | 89.0 | 10.0 | 1.0 | 0.011 | ∘ |
| | A8 | La = 0.02 | La | 88.0 | 10.0 | 2.0 | 0.023 | ∘ |
| | A15 | Ca = 0.0001 | Ca | 89.99 | 10.00 | 0.01 | 0.00011 | ∘ |
| | A9 | Ca = 0.02 | Ca | 88.0 | 10.0 | 2.0 | 0.023 | ∘ |
| | A10 | Ca = 0.05 | Ca | 80.0 | 10.0 | 5.0 | 0.063 | ∘ |
| | A16 | Mg = 0.001 | Mg | 89.9 | 10.0 | 0.1 | 0.0011 | ∘ |
| | A11 | Mg = 0.02 | Mg | 88.0 | 10.0 | 2.0 | 0.023 | ∘ |
| | A12 | Mg = 0.05 | Mg | 80.0 | 10.0 | 5.0 | 0.063 | ∘ |
| | A13 | Y = 0.02 | Y | 88.0 | 10.0 | 2.0 | 0.023 | ∘ |
| | A14 | Y = 0.05 | Y | 85.0 | 10.0 | 5.0 | 0.059 | ∘ |
| Comp. | A1 | Sr = 0.00001 | Sr | 89.999 | 10.000 | 0.001 | 0.000011 | x |
| Ex. | A2 | Li = 0.00005 | Li | 89.995 | 10.000 | 0.005 | 0.000056 | x |
| | A3 | La = 0.00008 | La | 89.998 | 10.000 | 0.008 | 0.000089 | x |
| | A4 | Ca = 0.10 | Ca | 80.0 | 10.0 | 10.0 | 0.125 | x |
| | A5 | Mg = 0.12 | Mg | 78.0 | 10.0 | 12.0 | 0.154 | x |
| | A6 | Y = 0.15 | Y | 75.0 | 10.0 | 15.0 | 0.200 | x |

| | | Resistivity | Resistivity | Crystallinity | Crystallinity | Average | |
|---|---|---|---|---|---|---|---|
| Examples/ | | upon film | after | upon film | after annealing | transmittance | |
| Comparative | | deposition | annealing | deposition | (250° C.) | after annealing | Etching |
| Examples | | [×10⁻⁴ Ω · cm] | [×10⁻⁴ Ω · cm] | [a or c] | [a or c] | [%] | [∘ or x] |
| Ex. | A1 | 4.5 | 2.1 | a | c | 96.9 | ∘ |
| | A2 | 5.2 | 2.6 | a | c | 93.5 | ∘ |
| | A3 | 6.3 | 6.3 | a | c | 91.1 | ∘ |
| | A4 | 4.3 | 2.7 | a | c | 90.9 | ∘ |
| | A5 | 4.7 | 4.6 | a | c | 87.8 | ∘ |
| | A6 | 5.3 | 8.8 | a | c | 92.1 | ∘ |
| | A7 | 5.0 | 2.0 | a | c | 98.3 | ∘ |
| | A8 | 5.6 | 2.0 | a | c | 98.8 | ∘ |
| | A15 | 3.4 | 2.1 | a | c | 97.4 | ∘ |
| | A9 | 4.9 | 3.0 | a | c | 96.2 | ∘ |
| | A10 | 7.5 | 9.9 | a | c | 95.1 | ∘ |
| | A16 | 4.0 | 2.0 | a | c | 95.6 | ∘ |
| | A11 | 4.9 | 3.3 | a | c | 95.5 | ∘ |
| | A12 | 7.5 | 7.9 | a | c | 94.1 | ∘ |
| | A13 | 6.5 | 2.3 | a | c | 93.2 | ∘ |
| | A14 | 7.9 | 2.7 | a | c | 93.7 | ∘ |
| Comp. | A1 | 2.9 | 1.8 | c | c | 97.5 | x |
| Ex. | A2 | 3.4 | 1.9 | c | c | 95.6 | x |
| | A3 | 3.2 | 1.9 | c | c | 98.2 | x |
| | A4 | 14.3 | 17.8 | a | a | 89.9 | ∘ |
| | A5 | 10.5 | 14.6 | a | a | 79.9 | ∘ |
| | A6 | 11.2 | 8.8 | a | a | 84.3 | ∘ |

### Example A17

In a manner similar to that of Production Example 1, a target (Sr=0.0001) was prepared, and the target was employed as a target for Example A17. The target was placed in a 4-inch DC magnetron sputtering apparatus, and a transparent conductive film of Example A17 was deposited from the target at a substrate temperature of about 20° C. (room temperature) while the oxygen partial pressure was varied from 0 to 3.0 sccm (corresponding to 0 to 1.1×10⁻² Pa).

The target was subjected to sputtering under the following conditions, whereby a film having a thickness of 1,200 Å was produced.

Target dimensions: φ=4 inches, t=6 mm
Mode of sputtering: DC magnetron sputtering
Evacuation apparatus: Rotary pump+cryopump
Vacuum attained: 5.3×10⁻⁶ [Pa]
Ar pressure: 4.0×10⁻¹ [Pa]
Oxygen pressure: 0 to 1.1×10⁻² [Pa]
Water pressure: 1.0×10⁻³ [Pa]
Substrate temperature: room temperature
Electric power for sputtering: 130 W (power density: 1.6 W/cm²)
Substrate used: Corning #1737 (glass sheet for liquid crystal display, t=0.8 mm)

### Comparative Example A7

By use of a target similar to that employed in Example A17, a transparent conductive film of Comparative Example A7 was deposited under the same conditions as in the cases of Examples A1 to A16.

### Test Example A5

As in the cases of Examples A1 to A16, a test was performed to determine whether or not optimum oxygen partial pressure was shifted after annealing in the case of Example A17 or Comparative Example A7. In addition, tests similar to those in Test Examples A1 to A4 were carried out. The results are shown in Table 3.

As is clear from Table 3, in the case of the chemical composition (Sr=0.0001), an amorphous film is not deposited under conditions where substantially no water is present (Comparative Example A7), but, when water partial pressure is increased to 1.0×10⁻³ [Pa], since water is incorporated, in the form of hydrogen, into a deposited film, the film is in an amorphous state, and optimum oxygen partial pressure is shifted after annealing.

This phenomenon is attributed to an increase in crystallization temperature of an amorphous film in the presence of water. This phenomenon effectively occurs particularly when an additive element is contained in a small amount. Specifically, when, for example, an amorphous film has a crystallization temperature of 100° C. or lower, the crystallization temperature can be raised by about 50 to about 100 degrees (° C.). Therefore, such an amorphous film is readily deposited.

The aforementioned phenomenon also occurs in the case where the additive element is Ba, which has an oxygen binding energy of 138 kJ/mol, which is nearly equal to that of Sr (i.e., 134 kJ/mol). Therefore, the phenomenon is expected to occur in the case where the additive element is Li, La, Ca, Mg, or Y, which has an oxygen binding energy falling within a predetermined range.

TABLE 3

| Example/ | | | | Chemical Composition [at. %] | | | Ratio to 1 | Shift In optimum |
|---|---|---|---|---|---|---|---|---|
| Comparative | | Sample | Additive | | | Additive | mol of In | oxygen partial pressure |
| Example | | Name | element | In | Sn | element | [mol] | [∘ or x] |
| Ex. | A17 | Sr = 0.0001 | Sr | 89.990 | 10.000 | 0.010 | 0.000111 | ∘ |
| | | Water partial | | | | | | |
| | | pressure: | | | | | | |
| | | 1.0 × 10⁻³ Pa | | | | | | |
| Comp. | A7 | Sr = 0.0001 | Sr | 89.990 | 10.000 | 0.010 | 0.000111 | x |
| Ex. | | | | | | | | |

| | | Resistivity | Resistivity | Crystallinity | Crystallinity | Average | |
|---|---|---|---|---|---|---|---|
| Example/ | | upon film | after | upon film | after annealing | transmittance | |
| Comparative | | deposition | annealing | deposition | (250° C.) | after annealing | Etching |
| Example | | [×10⁻⁴ Ω · cm] | [×10⁻⁴ Ω · cm] | [a or c] | [a or c] | [%] | [∘ or x] |
| Ex. | A17 | 4.0 | 1.9 | a | c | 97.8 | ∘ |
| Comp. | A7 | 3.0 | 1.9 | c | c | 97.1 | x |
| Ex. | | | | | | | |

1-9. (canceled)

10. A method for producing an indium-oxide-based transparent conductive film, characterized in that the method comprises:
a step of confirming that a sputtering target which is provided and which contains indium oxide and an additive element can deposit an amorphous film at a predetermined film deposition temperature, and that the obtained amorphous film can be crystallized through annealing at a predetermined annealing temperature;
a step of determining an oxygen partial pressure at which a crystallized film obtained through annealing at the predetermined annealing temperature has the lowest resistivity, which oxygen partial pressure differs from an optimum oxygen partial pressure at which the amorphous film deposited at the predetermined film deposition temperature has the lowest resistivity, and employing the thus-determined oxygen partial pressure, as a film deposition oxygen partial pressure;
a step of depositing an amorphous film through sputtering the sputtering target at the film deposition oxygen partial pressure; and
a step of crystallizing the amorphous film through annealing at the predetermined annealing temperature, to thereby produce an indium-oxide-based transparent conductive film.

11. A method for producing an indium-oxide-based transparent conductive film according to claim 10, wherein the method includes determining an optimum oxygen partial pressure at which a film produced at the annealing temperature has the lowest resistivity, and employing the thus-determined optimum oxygen partial pressure, as the film deposition oxygen partial pressure.

12. A method for producing an indium-oxide-based transparent conductive film according to claim 10, wherein the film deposition oxygen partial pressure is lower than the optimum oxygen partial pressure at which the deposited amorphous film has the lowest resistivity.

13. A method for producing an indium-oxide-based transparent conductive film according to claim 10, wherein the film deposition temperature is lower than 100° C.

14. A method for producing an indium-oxide-based transparent conductive film according to claim 10, wherein the additive element is at least one species selected from among Sn, Ba, Si, Sr, Li, La, Ca, Mg, and Y.

15. A method for producing an indium-oxide-based transparent conductive film according to claim 10, wherein the additive element contains Sn and at least one species selected from among Ba, Si, Sr, Li, La, Ca, Mg, and Y.

16. A method for producing an indium-oxide-based transparent conductive film according to claim 10, wherein the amorphous film is etched with a weakly acidic etchant and then crystallized through annealing.

17. A method for producing an indium-oxide-based transparent conductive film according to claim 10, wherein the annealing temperature falls within a range of 100 to 400° C.

18. A method for producing an indium-oxide-based transparent conductive film according to claim 10, which produces an indium-oxide-based transparent conductive film having a resistivity of 1.0×10⁻⁴ to 1.0×10⁻³ Ω·cm.
